(19) United States
(12) Patent Application Publication
(10) Pub. No.: US 2019/0169746 A1
(43) Pub. Date: Jun. 6, 2019

(54) GAS MIXING DEVICE AND METHOD, AND CVD APPARATUS INCLUDING THE SAME

(71) Applicant: BOE TECHNOLOGY GROUP CO., LTD., Beijing (CN)

(72) Inventor: Fengjuan LIU, Beijing (CN)

(21) Appl. No.: 16/050,011

(22) Filed: Jul. 31, 2018

(30) Foreign Application Priority Data
Dec. 4, 2017 (CN) 201711259251.1

(51) Int. Cl. C23C 16/455

(52) U.S. Cl. CPC C23C 16/45512; C23C 16/45506

(57) ABSTRACT

The present disclosure relates to a gas mixing device and a method, and a CVD apparatus including the gas mixing device. The gas mixing device includes: an inlet; a mixing tube in communication with the inlet, an inner wall of the mixing tube being formed with a spiral structure such that gases entering the mixing tube are rotatably travelling along the spiral structure and mixed; and an outlet through which the mixed gases in the mixing tube outflow.

### CROSS REFERENCE TO RELATED APPLICATIONS

This application claims the benefit of China Patent Application No. 201711259251.1 filed with the China Patent Office on Dec. 4, 2017, the entire content of which is hereby incorporated by reference.

### TECHNICAL FIELD

The present disclosure relates to a chemical vapor deposition process, and more particular, to a gas mixing device and a method, and a chemical vapor deposition (CVD for short) apparatus including the gas mixing device.

### BACKGROUND

For example, in a CVD deposition apparatus using a plurality of gases as raw materials, deposition uniformity is a fundamental element and is one of the most important factors affecting a deposited film layer in terms of meeting the requirements. There are many factors that affect the deposition uniformity, such as temperature uniformity, gas uniformity, discharging electric field uniformity. Diffusers affects the gas uniformity, in addition to that, whether the raw material gases are uniformly mixed affects uniformity of quality of the deposited film.

### SUMMARY

In an aspect, the present disclosure provides a gas mixing device, including:

an inlet;

a mixing tube in communication with the inlet, an inner wall of the mixing tube being formed with a spiral structure such that gases entering the mixing tube are rotatably travelling along the spiral structure and mixed; and

an outlet through which the mixed gases in the mixing tube outflow.

In an embodiment, the inner wall of the mixing tube includes a plurality of arcuate grooves, each of which is spirally disposed on the inner wall of the mixing tube in an airflow travelling direction.

In an embodiment, the plurality of arcuate grooves are disposed in parallel.

In an embodiment, the plurality of arcuate grooves are evenly arranged in a radial direction of the mixing tube.

In an embodiment, a ratio of a minimum inner diameter of the arcuate groove to a center of the mixing tube with respect to a maximum inner diameter of the arcuate groove to the center of the mixing tube is 1:1.05˜1:1.5.

In an embodiment, the mixing tube has a length of 0.2 meters to 2 meters.

In an embodiment, the gas mixing device further includes:

a mixing chamber, positioned between the mixing tube and the outlet, and having a cross-sectional dimension greater than a cross-sectional dimension of the mixing tube.

In an embodiment, the mixing tube and the mixing chamber are coaxially disposed.

In an embodiment, the mixing chamber is in a spherical shape.

In an embodiment, a diameter of the mixing tube is less than a diameter of the spherical mixing chamber.

In an embodiment, a ratio of the diameter of the mixing tube to the diameter of the mixing chamber is 1:2˜1:20.

In an embodiment, the gas mixing device further includes:

a gas merging pipe, located before the inlet and having a plurality of gas inlets, such that a plurality of gases pass through the gas inlets respectively to enter into the gas merging pipe.

In an embodiment, the gas mixing device further includes:

an emission tube located between the mixing chamber and the outlet, wherein the emission tube has a cross-sectional dimension different from a cross-sectional dimension of the mixing chamber.

In an embodiment, the gas merging pipe, the mixing tube, the mixing chamber, and the emission tube are each made of a corrosion resistant material.

Another aspect of the present disclosure provides a method for mixing gases, including:

mixing a plurality of gases in a mixing tube, the mixing tube having a first diameter and having an inner wall which is a spiral structure, to be outputted for chemical vapor deposition.

In an embodiment, the method for mixing gases further includes the gases outputted from the mixing tube passing through a mixing chamber having a second diameter and being outputted for chemical vapor deposition;

the first diameter being smaller than the second diameter.

Another aspect of the present disclosure provides a CVD apparatus including the gas mixing device as described above.

### BRIEF DESCRIPTION OF THE DRAWINGS

Specific embodiments of the present disclosure will be further described in detail below with reference to the accompanying drawings.

FIG. 1 is a schematic structural view showing a gas mixing device according to an embodiment of the present disclosure;

FIG. 2 is a schematic structural view showing a mixing tube according to an embodiment of the present disclosure;

FIG. 3 is a schematic structural view showing a gas merging pipe according to an embodiment of the present disclosure;

FIG. 4A is a schematic view of a cross-section of a mixing tube according to an embodiment of the present disclosure; and

FIG. 4B is a schematic view of a cross-section of a mixing tube according to another embodiment of the present disclosure.

### DETAILED DESCRIPTION

In order to explain the present disclosure more clearly, the present disclosure will be further described below in conjunction with preferred embodiments and the accompanying drawings. Similar components in the drawings are denoted by the same reference numerals. Those skilled in the art should understand that contents that are described in detail below are illustrative rather than restrictive, and are not intended to limit the protection scope of the present disclosure.

A gas mixing device is disclosed in an embodiment of the present disclosure. Generally, before raw material gases are injected into a deposition chamber, the raw material gases have already begun mixing and then are injected into a reaction chamber through a diffuser. However, it is not easy for gas having a smaller flow rate to be mixed evenly in gas having a larger flow rate. The gas mixing device according to the embodiment of the present invention achieves uniform mixing of the raw material gases.

The gas mixing device according to an embodiment of the present disclosure includes an inlet; a mixing tube in communication with the inlet, an inner wall of the mixing tube being formed with a spiral structure such that gases entering the mixing tube are rotatably travelling along the spiral structure and mixed; and an outlet through which the mixed gases in the mixing tube outflow.

During the traveling of the raw material gases along the spiral structure of the inner wall of the mixing tube, a traveling direction of the raw material gases is changed for multiple times by the constraint of the spiral structure of the inner wall of the mixing tube, such that the plurality of gases are thoroughly mixed in the same pipeline. Referring to FIG. 1, the gas mixing device according to an embodiment of the present disclosure includes a mixing tube 1, a mixing chamber 2 connected to the mixing tube, wherein an inner wall of the mixing tube is a spiral structure 11. The mixing tube 1 and the mixing chamber 2 can be integrally welded or can be detachably connected together hermetically. For the convenience of cleaning and replacement, in the present disclosure, the mixing tube 1 and the mixing chamber 2 are according to an embodiment of the present disclosure provided to be detachably and hermetically connected, and the mixing tube 1 and the mixing chamber 2 are coaxially disposed, to guarantee a speed of the mixed gases during travelling, which is favorable for thorough mixing of the gases.

According to an embodiment of the present disclosure, an inlet of the mixing chamber 2 is connected to the mixing tube 1, and an outlet of the mixing chamber 2 is connected to an emission tube 3, which is configured to emit the uniformly mixed gases in the mixing chamber 2 to a subsequent chamber. When there are many kinds of gases, an inner wall of the emission tube 3 can also be a spiral structure, to further mix the emitted gases. The spiral inner wall of the mixing tube 1 facilitates mixing of the gases of different flow rates, and the gases discharged from the mixing tube 1 is further mixed in the mixing chamber 2 and then emitted from the emission tube 3. It follows that gas mixing efficiency will be increased, and mixing uniformity of the gases will be improved.

According to an embodiment of the present disclosure, the mixing chamber 2 is designed as a spherical shape, and the mixing chamber 2 functions to further store and make a mix on the mixed gases in the mixing tube 1 which form an eddy current, so that the mixed gases are more uniformly mixed in the mixing chamber, and meanwhile, the mixed gases in the mixing chamber 2 can be stirred due to the inertia effect of the gas eddy just entering the mixing chamber 2 from an outlet of the mixing tube 1, thereby facilitating gas mixing and improving the mixing efficiency. In the meanwhile, the mixing chamber 2 adopts a spherical design to prevent the mixed gases from stagnating in a certain corner of the mixing chamber 2, which avoids insufficient gas mixing and improves the mixing efficiency.

A diameter of the mixing tube 1 is smaller than a diameter of the spherical mixing chamber 2. This ensures that there is sufficient space for the mixed gases to be stored in the mixing chamber 2. Further, the mixed gases enter the mixing chamber 2 having a relatively large diameter from the mixing tube 1 having a relatively small diameter, and then the mixed gases are discharged from the emission tube 3 having a relatively small diameter, the multiple changes in diameter makes the flow rate of the mixed gases during the travelling changed, thereby promoting the mixing of the gases. Specifically, a ratio of the diameter of the mixing tube 1 to the diameter of the mixing chamber 2 is 1:2˜1:20. In such a manner the relationships between the flow rate of the mixed gases in the mixing tube 1 and the flow rate of the mixed gases in the mixing chamber 2 can be controlled to ensure that the gases are sufficiently mixed while increasing mixing and emission speed, and increasing the mixing efficiency.

A length of the mixing tube 1 is 0.2 meters to 2 meters. If the length of the mixing tube 1 is too short, the mixed gases have reached the outlet of the mixing tube 1 without being sufficiently mixed, which fails to facilitate the mixing; and if the length of the mixing tube 1 is too long, a velocity of the mixed gases gradually decreases during the spiral travelling, and the mixed gases will stagnate in the mixing tube 1 at last, and cannot reach the mixing chamber 2, which reduces the mixing efficiency.

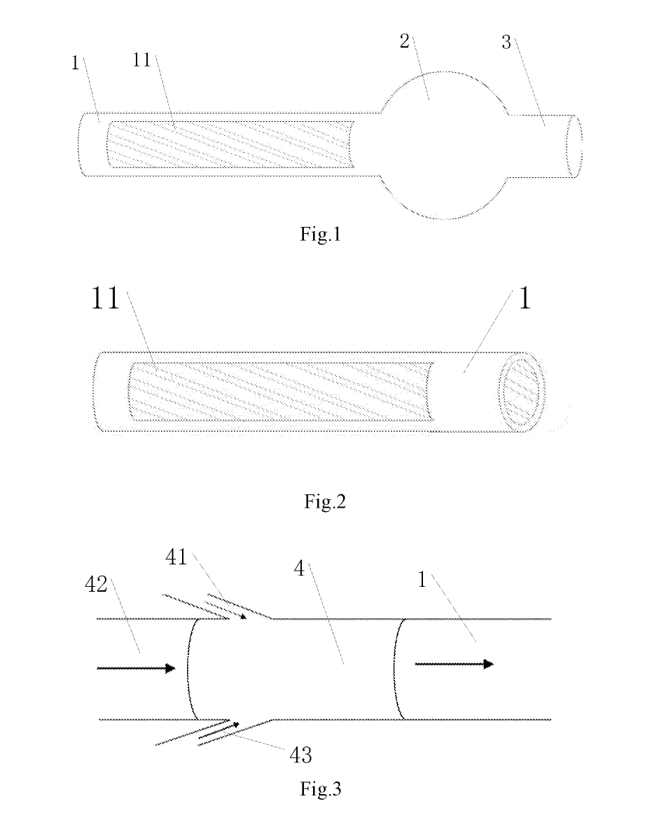

Referring to FIG. 2, an inner wall of the mixing tube 1 according to an embodiment of the present disclosure includes a plurality of arcuate grooves 11, each of the arcuate grooves 11 is spirally disposed on the inner wall of the mixing tube 1 in an airflow travelling direction, and all of the arcuate grooves 11 are disposed in parallel to each other and will not make contact with each other on the inner wall of the mixing tube 1, and a pitch that each of the arcuate grooves 11 rotates around the inner wall of the mixing tube 1 is the same, in this way, it ensures that the velocity of the gases during the rotary travelling along each of the arcuate grooves 11 is the same.

According to an embodiment of the present disclosure, all the arcuate grooves 11 are evenly arranged in a radial direction of the mixing tube 1, and a distance between each two of the arcuate grooves 11 is equal, so that the mixed gases will be uniformly forced throughout the mixing tube 1 during the rotary travelling along the arcuate grooves 11, and will not shake violently or shift, meanwhile the speed of the gases during the rotary travelling along each of the arcuate grooves 11 is the same.

As shown in FIG. 3, an inlet of the mixing tube 1 according to an embodiment of the present disclosure is connected to an outlet of a gas merging pipe 4, which has a plurality of gas inlets 41, 42 and 43. Channels of the gas inlets are capable of passing gases at different flow rates. Various gases enter the gas merging pipe 4 through the respective gas inlets, to be preliminarily mixed. The preliminary mixed gases enter the mixing tube 1, and are spirally advancing along the spiral grooves 11 of the mixing tube 1, and further mixed during the advancing, so that the gases entering the mixing tube 1 are the mixed gases subject to the preliminary mixing, in this way, the gases of different flow rates are prevented from directly entering the different arcuate grooves in the mixing tube 1, thereby improving the mixing efficiency.

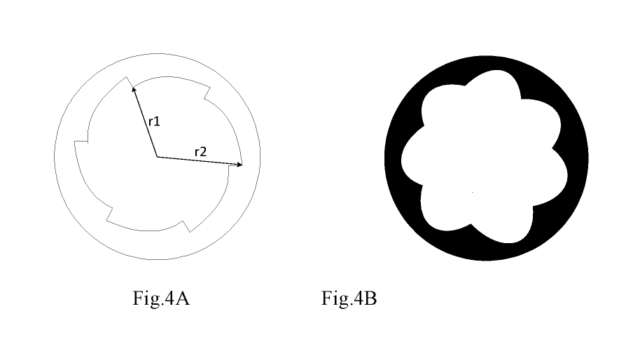

As shown in FIG. 4A, an embodiment of the present disclosure provides a view of a cross-section of a mixing tube 1. A ratio of a minimum radius r1 of an arcuate groove 11 to a center of the mixing tube with respect to a maximum radius r2 of the arcuate groove 11 to the center of the mixing tube is 1:1.05˜1:1.5, according to an embodiment of the present disclosure 1:1.05˜1:1.1. A depth of the arcuate groove 11 is limited within a certain range, to ensure that the mixed gases, after entering the mixing tube 1, may be rotatably advanced along the arcuate grooves 11 and sufficiently mixed. If the arcuate grooves 11 are too small, the mixed gases cannot be rotatably advancing along the arcuate grooves 11, or only a small part of the gases rotate along the arcuate grooves 11, leading to not capable of achieve the mixing effect; and if the arcuate grooves 11 are too large, the arcuate grooves 11 will block the mixed gases, leading to retracts a traveling speed of the mixed gases, and affects the mixing efficiency.

In addition, the view of the cross-section of the mixing tube 1 can also be designed as with a shape illustrated in FIG. 4B. The shape of the arcuate grooves 11 includes, but is not limited to, the above-described two shapes, as long as the shape of arcuate grooves 11 allows the mixed gases to be rotatably travelling along the arcuate grooves, the shape will fall into the scope of the present disclosure.

The mixing tube 1, the mixing chamber 2, the emission tube 3 and the gas merging pipe 4 are all made of an anti-corrosion material, to prevent the device from being corroded by the gases during the mixing of the gases, which results in gas leakage and thus environment pollution, and harm on human body, and reduces work efficiency.

An embodiment of the present disclosure also provides a method for mixing gases, including the following step.

In step S1, various gases are mixed in a mixing tube having a first diameter and including an inner wall which is with a spiral structure.

First, gases of different flow rates are injected into the same tube to be preliminarily mixed, and then the mixed gases are injected into the mixing tube having a first diameter and having an inner wall which has a spiral structure, and then the mixed gases are rotatably travelling along the spiral inner wall of the mixing tube, and are gradually mixed uniformly during the travelling.

An embodiment of the present disclosure also provides a method for mixing gases, in addition to the step S1, further including the following step.

In step S2, the gases outputted from the mixing tube are passed through a mixing chamber having a second diameter and outputted for chemical vapor deposition.

The mixed gases mixed in the mixing tube having a first diameter enter the mixing chamber having a second diameter, and an eddy current formed by the mixed gases stirs the mixed gases in the mixing chamber to further mix the gases, and the other end of the mixing chamber is provided with an emission outlet, and the uniformly mixed gases are discharged from the mixing chamber through an emission tube for chemical vapor deposition of an array substrate.

The first diameter is smaller than the second diameter, which ensures that there is a sufficient storage space for the mixed gases to be mixed and stirred after the mixed gases enter the mixing chamber, and the changes in the diameters can change the flow rates of the mixed gases when advancing, thereby promoting the mixing of the gases.

An embodiment of the present disclosure also provides a CVD apparatus for chemical vapor deposition of an array substrate of a display device, wherein the gas mixing device in the above-described embodiments is used for the mixing of gases in the apparatus, to improve the gas mixing efficiency. Moreover, the gas mixing device of the present disclosure is particularly suitable for a CVD apparatus into which a plurality of gases are inputted, particularly gases flow rates of which are significantly different, which ensures uniform mixing of various unstripped gas and provides a uniform film forming quality.

It is apparent that the above-described embodiments of the present disclosure are merely examples provided for clearly describing the present disclosure, and are not restrictive of the embodiments of the present disclosure, and those skilled in the art can also make other different forms of changes and modifications on the basis of the foregoing descriptions. All of the embodiments cannot be exhaustivity described herein. The obvious changes and modifications made based on the technical solutions of the present disclosure fall into the protection scope of the present disclosure.

What is claimed is:

1. A gas mixing device, comprising:
an inlet;
a mixing tube in communication with the inlet, an inner wall of the mixing tube being formed with a spiral structure such that gases entering the mixing tube rotatably travel along the spiral structure and are mixed; and
an outlet through which the mixed gases in the mixing tube outflow.

2. The gas mixing device according to claim 1, wherein the inner wall of the mixing tube comprises a plurality of arcuate grooves, each spirally disposed on the inner wall of the mixing tube in an airflow travelling direction.

3. The gas mixing device according to claim 2, wherein the plurality of arcuate grooves are disposed in parallel.

4. The gas mixing device according to claim 2, wherein the plurality of arcuate grooves are evenly arranged in a radial direction of the mixing tube.

5. The gas mixing device according to claim 4, wherein a ratio of a minimum inner diameter of the arcuate groove to a center of the mixing tube with respect to a maximum inner diameter of the arcuate groove to the center of the mixing tube is 1:1.05˜1:1.5.

6. The gas mixing device according to claim 1, wherein the mixing tube has a length of 0.2 meters to 2 meters.

7. The gas mixing device according to claim 1, further comprising:
a mixing chamber, positioned between the mixing tube and the outlet, and having a cross-sectional dimension greater than a cross-sectional dimension of the mixing tube.

8. The gas mixing device according to claim 7, wherein the mixing tube and the mixing chamber are coaxially disposed.

9. The gas mixing device according to claim 7, wherein the mixing chamber is in a spherical shape.

10. The gas mixing device according to claim 9, wherein a diameter of the mixing tube is less than a diameter of the spherical mixing chamber.

11. The gas mixing device according to claim 9, wherein a ratio of the diameter of the mixing tube to the diameter of the mixing chamber is 1:2˜1:20.

12. The gas mixing device according to claim 7, further comprising:
a gas merging pipe, located before the inlet and having a plurality of gas inlets, such that a plurality of gases pass through the gas inlets respectively to enter into the gas merging pipe.

13. The gas mixing device according to claim 7, further comprising:
an emission tube located between the mixing chamber and the outlet, wherein the emission tube has a cross-sectional dimension different from a cross-sectional dimension of the mixing chamber.

14. The gas mixing device according to claim 12, further comprising:
an emission tube located between the mixing chamber and the outlet, wherein the emission tube has a cross-sectional dimension different from a cross-sectional dimension of the mixing chamber.

15. The gas mixing device according to claim 14, wherein the gas merging pipe, the mixing tube, the mixing chamber, and the emission tube are each made of a corrosion resistant material.

16. The gas mixing device according to claim 1, further comprising:
a gas merging pipe, located before the inlet and having a plurality of gas inlets, such that a plurality of gases pass through the gas inlets respectively to enter into the gas merging pipe.

17. The gas mixing device according to claim 16, wherein the gas merging pipe and the mixing tube are each made of a corrosion resistant material.

18. A method for mixing gases, comprising:
mixing a plurality of gases in a mixing tube, the mixing tube having a first diameter and an inner wall with a spiral structure, to be outputted for chemical vapor deposition.

19. The method for mixing gases according to claim 18, further comprising:
passing the gases outputted from the mixing tube through a mixing chamber having a second diameter and being outputted for chemical vapor deposition, the first diameter being smaller than the second diameter.

20. A chemical vapor deposition (CVD) apparatus comprising a gas mixing device according to claim 1.
